(19) United States
(12) Patent Application Publication
(10) Pub. No.: US 2014/0253137 A1
(43) Pub. Date: Sep. 11, 2014

(54) TEST PATTERN DESIGN FOR SEMICONDUCTOR DEVICES AND METHOD OF UTILIZING THEREOF

(71) Applicant: MACRONIX INTERNATIONAL CO., LTD., Hsin-chu (TW)

(72) Inventors: Yen Chuang, New Taipei City (TW); Che-Lun Hung, Hsinchu County (TW); Hsiao-Leng Li, Miaoli County (TW)

(73) Assignee: MACRONIX INTERNATIONAL CO., LTD., Hsin-chu (TW)

(21) Appl. No.: 13/790,253

(22) Filed: Mar. 8, 2013

(51) Int. Cl. G01R 31/265; H01L 23/00; H01L 23/498

(52) U.S. Cl. CPC G01R 31/265; H01L 23/49866; H01L 24/64
USPC 324/501; 324/750.01; 257/741; 438/666

(57) ABSTRACT

Methods and systems for the detection of defects in semiconductors, semiconductor devices, or substrates are provided. Semiconductors, semiconductor devices or substrates having novel test patterns and or designs are also provided. The semiconductors, semiconductor devices or substrates have a plurality of line patterns, which, in response to a responsive stimulus such as electron beam irradiation, produces a response. The responsive stimulus may include an electron beam irradiation, and the image data can be collected and processed to produce an image or images that indicate the presence or absence of surface and/or internal defects.

### TECHNOLOGICAL FIELD

The invention generally relates to a semiconductor device. In particular, the invention relates to a novel test pattern design and a method of using such a test pattern design to identify defects in a deposited metal layer.

### BACKGROUND

Fabrication of semiconductor devices typically requires creating line patterns of conducting metal that interconnect various layers of the semiconductor device. This may involve a “damascene process.” Accordingly, line patterns may be formed on or within a dielectric layer of a surface of the semiconductor device. For example, a line pattern may be etched in the insulating material and filled with a conducting metal. A selective removal process, such as mechanical polishing or chemical mechanical polishing, may be used to ensure the conducting metal is disposed in the etched line pattern.

The continuing trend in the semiconductor industry is toward higher device densities but without compromising the efficiency of the performance of the device. The device dimensions of the semiconductors formed on substrates (collectively referred as wafers) continue to be scaled down to sub-micron levels to achieve this purpose. For example, the width and the spacing of interconnecting lines, spacing and diameter of contact holes, and surface geometry such as corners and edges are various features that continue to become smaller. When the conducting metal such as copper is deposited in these narrow/small interconnecting lines, the conducting metal may not completely fill the entire diameter of the trench resulting in the formation of a gap or a pit.

Additionally, due to its reactivity, copper has the tendency to form bridges (“oxide bridge”) between the surrounding dielectric or insulating layer. This results in a decrease in the conductivity of the conducting lines/layers. Also, oxide bridges may cause incomplete separation of the dielectric layer from the conducting line/layers. This leads to the contamination of the dielectric or oxide layer. A contaminated dielectric layer may cause losses in the insulation properties of the dielectric layer, resulting in short circuits or current leakage.

Conventional methods for detecting defects, such as gaps, pits, or oxide bridges, are generally limited to optical detection devices that are only capable of detecting surface defects. Other methods for detecting internal defects typically involve tedious and time consuming defect detection techniques. There remains a need in the art for improved methods of testing for defects in semiconductor conductive layers. Additionally, there remains a need for development of fast, in-line detection processes that can improve the efficiency of semiconductor fabrication processes while reducing the cost associated with the test measurements. There also remains a need in the art for the development of improved defect detection methods that are reliable.

### SUMMARY OF THE INVENTION

The following is a summary of the invention to provide a basic understanding of some aspects of the invention. The summary is not intended to identify key/critical elements of the invention or delineate the scope of the invention. Its sole purpose is to present some concepts of the invention in a simplified form as a prelude to the more detailed description that is presented later.

One aspect of the invention is a method of inspecting a semiconductor device comprising the steps of providing the semiconductor device having a plurality of line patterns disposed on a substrate, exposing the plurality of line patterns to a responsive stimuli, and measuring a response of the plurality of line patterns to the responsive stimuli. The response of the plurality of line patterns may, for example, indicate the presence of a surface defect or an absence of a surface defect, an internal defect such as a pit or an oxide bridge, or any combination thereof. In certain embodiments of the invention, the plurality of line patterns are connected by at least one interconnecting line pattern. In some aspects of the invention, the method is an in-line, continuous process.

In some embodiments of the invention, the responsive stimuli comprise at least one of an irradiation, a conductance, a magnetic resonance, an acoustical stimulation, and an electrical stimulation. In certain embodiments of the invention, the responsive stimuli comprise an electron beam radiation. According to such embodiments, the method of detection may further comprise collecting data from the electron beam radiation, and developing at least one or more images showing any one of the presence of the surface defect and the absence of the surface defect, the internal defect, and any combination thereof.

In certain embodiments of the invention, the method of inspecting a semiconductor device may additionally comprise the step of applying an external electrical field to the semiconductor device. In certain embodiments of the invention, the external electric field is applied such that there is an improvement in the contrast of the developed image.

In some embodiments of the invention, the plurality of line patterns comprises a plurality of trenches on the surface of the semiconductor device and at least one conducting metal deposited in the plurality of trenches.

An aspect of the invention provides a semiconductor device comprising a substrate, a dielectric layer, a plurality of conductive patterns disposed in the dielectric layer, and at least one interconnecting line pattern configured to connect the plurality of conductive line patterns. In some embodiments of the invention, the conductive line patterns of the plurality of conductive line patterns are parallel to one another. In certain other embodiments, the at least one interconnecting line pattern is proximate to a terminus of and perpendicular to the plurality of conductive line patterns.

Another aspect of the invention includes a method of fabricating a semiconductor device comprising the steps of providing a substrate, forming at least one of a dielectric layer on the substrate, etching a plurality of trenches in the dielectric layer, etching at least one interconnecting trench in the dielectric layer interconnecting the plurality of trenches, and depositing a conductive material in the plurality of trenches and the at least one interconnecting trench. In some embodiments of the invention, the conductive material is selected from the group consisting of aluminum, copper, tungsten, gold, any alloy thereof, and any combination thereof.

Certain other embodiments of the invention include methods of inspecting a semiconductor device comprising providing the semiconductor device having a substrate, a dielectric layer, a plurality of conductive line patterns disposed in the dielectric layer, and at least one interconnecting conductive line pattern configured to connect the plurality conductive line patterns, irradiating the semiconductor device with an electron beam radiation, receiving image data resulting from the irradiation, and developing an image of the semiconductor device from the image data, wherein the image identifies any one of a presence or an absence of a defect. In some embodiments, these methods are in-line, continuous methods. Certain embodiments of the invention are directed to apparatus for detecting at least one of an internal defect and a surface defect of a semiconductor device.

Certain other embodiments of the invention provide a system for detecting a defect in a semiconductor device, the semiconductor device having a test pattern, the semiconductor device comprising a substrate; a dielectric layer disposed over the substrate; a plurality of conductive line patterns disposed in the dielectric layer; and at least one interconnecting line pattern configured to connect the plurality of line patterns. The system may additionally comprise an irradiating device for providing energy to the test pattern; a receiving device to receive data resulting from the irradiating device; and an imaging device to display an image that detects any one of a surface defect, an internal defect, and any combination thereof in the semiconductor device. According to certain embodiments of the invention, the system may additionally comprise an external electric field generator located proximate to the substrate.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE DRAWINGS

Having thus described the invention in general terms, reference will now be made to the accompanying drawings, which are not necessarily drawn to scale, and wherein:

FIG. 1A illustrates a cross-sectional view of a semiconductor device having an oxide trench fabricated according to an embodiment of the invention;

FIG. 1B illustrates a cross-sectional view of a semiconductor device taken along the section line labeled BB′ in FIG. 1A;

FIG. 2A illustrates a cross-sectional view of a semiconductor device having a conductive metal deposited in the trenches fabricated according to an embodiment of the invention;

FIG. 2B illustrates a cross-sectional of a semiconductor device having an oxide trench taken along the section line labeled BB′ in FIG. 2A;

FIG. 3A illustrates an embodiment of the inventive test pattern design showing certain defects;

FIG. 3B illustrates an electron beam radiation image of the defective test pattern of FIG. 3A according to an embodiment of the invention;

FIG. 4A illustrates an electron beam inspecting apparatus that may be used to detect the defects in a semiconductor device test pattern design, according to an embodiment of the invention;

FIG. 4B is a diagrammatic representation of electron beam irradiation of one embodiment of the inventive test pattern design;

FIG. 5 illustrates an energy diagram of a positive mode and negative mode electron beam radiation in certain embodiments of the invention;

FIGS. 6A-6E illustrates the steps of detecting defects using a leap scan method according to an embodiment of the invention; and

FIGS. 7A-7E illustrates the steps of detecting defects using a continuous scan method according to an embodiment of the invention.

### DETAILED DESCRIPTION

Some embodiments of the invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a semiconductor device” includes a plurality of semiconductor devices.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

The invention generally relates to an apparatus and a method of detection of internal and/or surface defects, in particular, in the semiconductor device fabrication processes. The subject invention is also related to inventive test pattern designs on a semiconductor device or substrate and fabricating semiconductor devices having such designs.

As used herein, a “semiconductor” or “semiconductor device” means a semiconductor device or a semiconductor substrate. Generally, these include devices or substrates known by those having ordinary skill in the art of semiconductors. The semiconductor devices, hitherto unknown, which may be developed in the future, are also considered to be semiconductors of the invention.

As used herein, the term “semiconductor substrate” is defined to mean any construction comprising a semiconductive material, including but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates further described herein.

In some embodiments, the methods of the invention may be directed to certain semiconductor devices. The methods of the invention may be suitable to certain semiconductor devices known by persons having ordinary skill of art having the benefit of this disclosure. In some embodiments of the invention, the semiconductor device may be a semiconductor memory device. The semiconducting memory device may be a random access memory (RAM) device or a read only memory (ROM) device. The RAM device can be selected from the group consisting of dynamic random access memory (DRAM), fast page mode DRAM (FPM DRAM), extended data out DRAM (EDO DRAM), video random access memory (VRAM), synchronous dynamic random access memory (SDRAM), double date rate SDRAM (DDR SDRAM), Rambus DRAM (RDRAM), synchronous graphics RAM (SGRAM), pseudostatic RAM (PSRAM), mageneto resistive RAM (MRAM) and static RAM (SRAM). The ROM device is selected from the group consisting of mask programmed ROM, programmable ROM (PROM), erasable programmable read only memory (EPROM) and electrically erasable programmable ROM (EEPROM). In some embodiments of the invention, the semiconductor memory device is a flash memory device.

In the high density processes of semiconductor device fabrication, the damascene process may be used to improve the profiles of metal interconnect, i.e. the conducting metal deposited in the trenches forming a metal interconnect line pattern. In a damascene process, a conducting metal may be deposited into a trench formed within a dielectric layer. The trench may be etched into the dielectric layer. A metal may be blanket deposited into the trench formed within the dielectric layer. Any portion of deposited metal that lies outside of the trench may be removed using, for example, a purely mechanical polishing process, a chemical mechanical planarization process, and/or other planarization processes. According to certain embodiments of the invention, the damascene process may be desirable because the sidewall profile of each interconnect is defined by patterning and etching the dielectric layer rather than through patterning the metal itself. The difficulty of achieving substantially vertical interconnect sidewalls through the use of a metal etch process is well-known in the field of semiconductor processing. Additionally, a damascene process may result in a substantially planer semiconductor surface upon which a subsequent interconnect level may be fabricated.

Generally, the semiconductor substrates may comprise inert dielectric layers and conducting layers. For example, some embodiments of the invention may involve semiconductor substrates having materials selected from the group consisting of gallium arsenide (GaAs), germanium, silicon, silicon germanium, lithium niobate, and compositions containing silicon such as crystalline silicon, silicon dioxide, and combination thereof. In certain embodiments of the invention, the semiconductor substrate is a semiconductor wafer, in particular, a silicon wafer. The term “wafer” refers to a semiconductor structure, a substrate or a device during any stage of the fabrication of a semiconductor device, for example. Examples of dielectric materials may include silicon containing spin-on glass such as alkoxysilane polymer, a siloxane polymer, a silsesquioxane polymer, a poly(arylene ether), a fluorinated poly(arylene ether), other polymer dielectrics, nanoporous silica or mixtures thereof.

The dielectric layer may be formed by any suitable technique. For example, chemical vapor deposition (CVD), plasma enhanced chemical vapor deposition (PECVD), low pressure chemical vapor deposition (LPCVD), high pressure chemical vapor deposition (HPCVD). Polymeric dielectrics can also be formed by using spin coating, dip-coating, spraying or roller coating.

The dielectric layer may then be subjected to selective etching to produce contact tunnels/trenches/grooves/openings and/or vias. The etching can be carried out using any suitable etchants. The oxide layer may be etched using, for example, a wet process, a dry process, and any combination thereof. For example, wet oxide etching may be carried out in solutions containing buffered or diluted hydrofluoric acid (HF). HF may be capable of etching an oxide layer in a very controlled manner and yet still be very selective. An example of dry oxide etching includes a plasma-based process using, for example, fluorocarbon gases such as tetrafluoromethane (CF₄), hexafluoroethane C₂F₆, fluoroform CHF₃, or octaflurocyclobutane (C₄F₈). Such gases may also include any one of or any combination of oxygen (O₂), nitrogen (N₂), Argon (Ar), or Helium (He). The wet or dry oxide processes of the invention may be used, for example, in batch and/or single wafer platforms.

After the trenches or grooves have been formed, these are filled with a conductive material, typically with a conductive material. The conductive material may be any suitable material, such as a conductive metal, conductive metal alloys, conductive metal oxides, conductive polymer films, semiconductive materials, and the like. Specific examples of conductive materials include any of aluminum, chromium, copper, germanium, gold, magnesium, manganese, tungsten, zinc, any alloys thereof, and any combinations thereof. Any technique known in the art may be used to fill the trenches or openings. Exemplary methods may include electroplating, electroless filling, sputtering, evaporation, deposition, and the like, and may be used to fill the trenches or openings.

Regardless of the method for depositing the conductive material, semiconductor device fabrication typically requires deep and narrow contact lines. As such, it is inevitable that surface and internal defects may be developed during this process. Surface defects could be any of the defects that are common during the semiconductor device fabrication processes. For example, the surfaces may be any of or any combination of uneven, contaminated with other materials or scratched. Internal defects may include any defect that may be formed internal to the surface of the conducting lines/pattern during the semiconductor device fabrication process. For instance, the internal defects could be the defects that may go undetected when using a conventional surface defect detection method. These internal defects may impact the flow-through conductance of the conducting lines. For example, internal defects such as “pits” or “oxide bridges” may severely limit the performance of a semiconductor device or a semiconductor substrate. “Pits” in this context mean the formation of gaps or voids or breaks within a conducting line during a metal deposition process. “Oxide bridge” refers to the formation of a bridge between the semiconductor substrate through the conducting line. For example, an oxide bridge may form that connects the dielectric layer and the inert layer through the conducting line. Such an oxide bridge may not be detected using conventional surface detection techniques.

An aspect of the invention also includes line patterns formed on the semiconductor devices or semiconductor substrates. In particular embodiments, the inventive line designs or patterns are formed on the surfaces of the semiconductor substrates or devices. The inventive line patterns may be advantageously used in the fabrication of various interconnect structures and conductive patterns, such as metal lines, damascene structures, dual damascene structures, metal plugs, wirings, circuits and the like. As appreciated by a person skilled in the art having the benefit of this disclosure, the patterns of the invention may be formed using, for example, a metal etching process (i.e. photolithography of the deposited metal followed by etching the metal) or a damascene process. In certain embodiments of the invention, a modified damascene process, such as dual damascene process may be used.

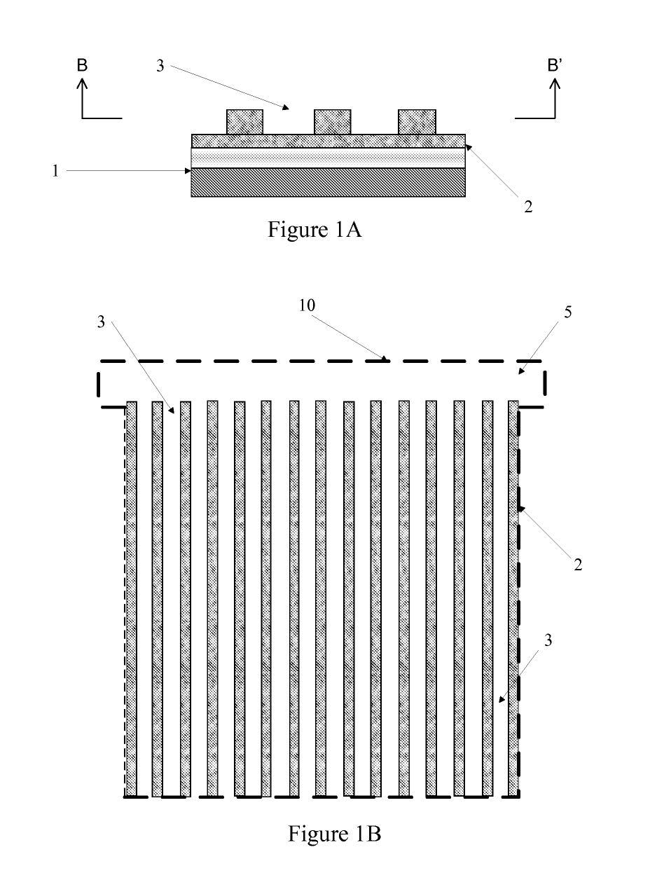

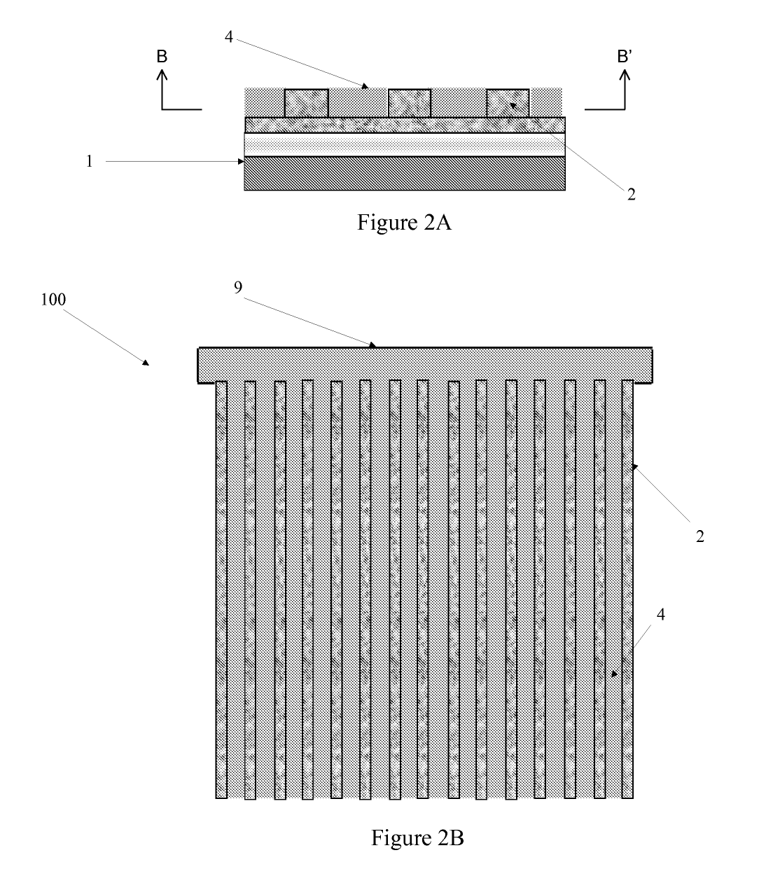

FIGS. 1A and 2A illustrate a cross-sectional view of a semiconductor device manufactured according to an embodiment of the invention. FIGS. 1B and 2B are cross-sectional views taken along the section view line labeled BB′ in FIGS. 1A and 2A, respectively. With reference to these FIGS. 1A-2B, a substrate 1 is provided, a dielectric layer 2 is formed on the substrate 1, and at least one trench is formed in the substrate 1. According to FIG. 1B, the test pattern is defined by a test pattern boundary 10. The trenches in the dielectric layer 2 comprise a plurality of line trenches 3 that are substantially parallel to each other and an interconnecting trench 5, wherein the interconnecting trench 5 connects the plurality of line trenches 3. According to this illustrative embodiment of the invention, the interconnecting trench 5 is perpendicular and proximate to the terminus of the plurality of line trenches 3.

With reference to FIGS. 2A and 2B, both the interconnecting trench 5 and the plurality of lines trenches 3 are filled with a conducting material to form a conductive line 4 and a conductive interconnecting structure 9 to form a test pattern 100 according to an embodiment of the invention. The conducting material may comprise a conducting metal, metal alloys, or combination of metals or metal alloys. In certain embodiments of the invention, copper may be used as the conducting metal.

According to one aspect of the invention, the plurality of conductive lines of the invention is exposed to a responsive stimuli. In other embodiments of the invention, semiconductor devices, semiconductor substrates (i.e. semiconductor wafers) may be exposed to the responsive stimuli. The responsive stimuli may comprise any stimulus that is known within the art, which would induce a response from the conductive line pattern. In some embodiments of the invention, the responsive stimuli comprises at least one of an irradiation, a conductance, a magnetic resonance, an acoustical stimulation, and an electrical stimulation.

In one embodiment of the invention, the plurality of conductive line patterns is irradiated with an electron beam radiation. In some embodiments of the invention, the semiconductor device and/or substrate is irradiated with an electron beam radiation.

Further pursuant to this embodiment of the invention, a surface scanning technique may be used. For example, a surface of the article or object under inspection may be irradiated with an electron beam radiation, and image data may be obtained from the number of secondary electrons emitted from the surface of the article. The number of secondary electrons emitted from the surface of the article may vary according to the properties of the sample. A pattern or design formed on the surface of the article, such as a semiconductor substrate, may be inspected in a high throughput fashion based on the image data provided by the invention.

A scanning electron microscope (SEM) may be used in certain embodiments of the invention. Accordingly, an electron beam may be focused on an article, for example, a semiconductor device, and irradiated with an electron beam. A semiconductor device, such as a silicon wafer, may be placed on a stage, and the stage moved in a direction perpendicular to the electron beam scanning direction. Irradiation using a focused electron beam may cause secondary electrons to be emitted from the semiconductor device. The secondary electrons may be detected using a detector (a scintillator plus a photomultiplier) or a semiconductor type detector (a PIN diode type detector). The coordinates of the position of the irradiation with the electron beam and the number of secondary electrons (signal intensity) may be combined to produce an image. The collected image data may be stored in a storage unit. Alternatively, the image data may be output on to a cathode ray tube. The image thus obtained may show defects in the semiconductor device. In particular, the methods of the invention may show whether there are any defects in or within the conducting line pattern.

In one particular embodiment of the invention, the following electron beam irradiation conditions can be employed. Accordingly, electron beam column conditions include a landing energy of between about 200 to about 2500 volts, a No. 5 extracting of from about 0 to about 3000 units, current of from about 0 to about 90 Amperes, and an aperture of about 0 to about 30 units. The sample is scanned in both X and Y directions. According to an embodiment of the invention, any one of or combination of an array and a periphery of a semiconductor device may be irradiated using an electron beam irradiator or irradiating device for detecting defects.

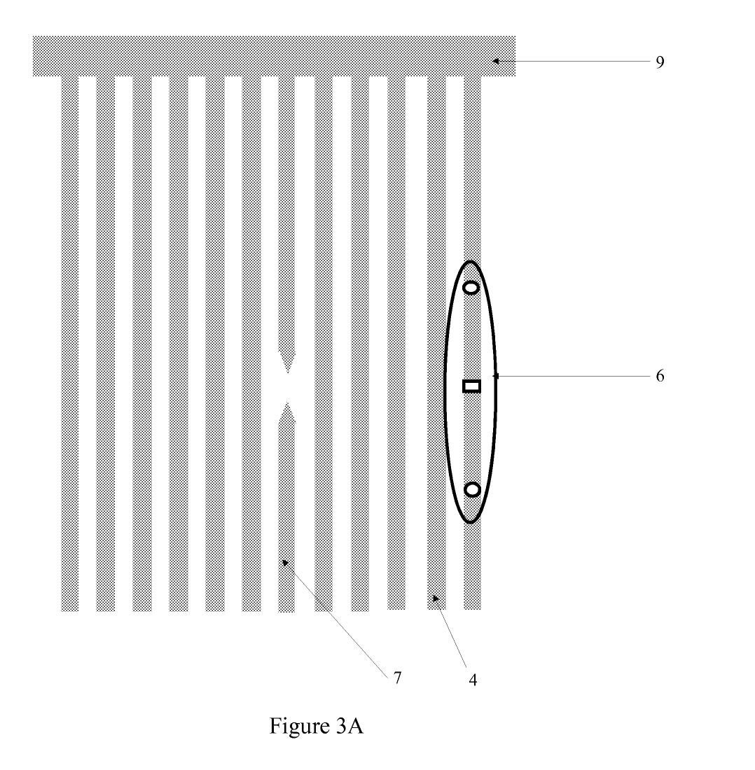

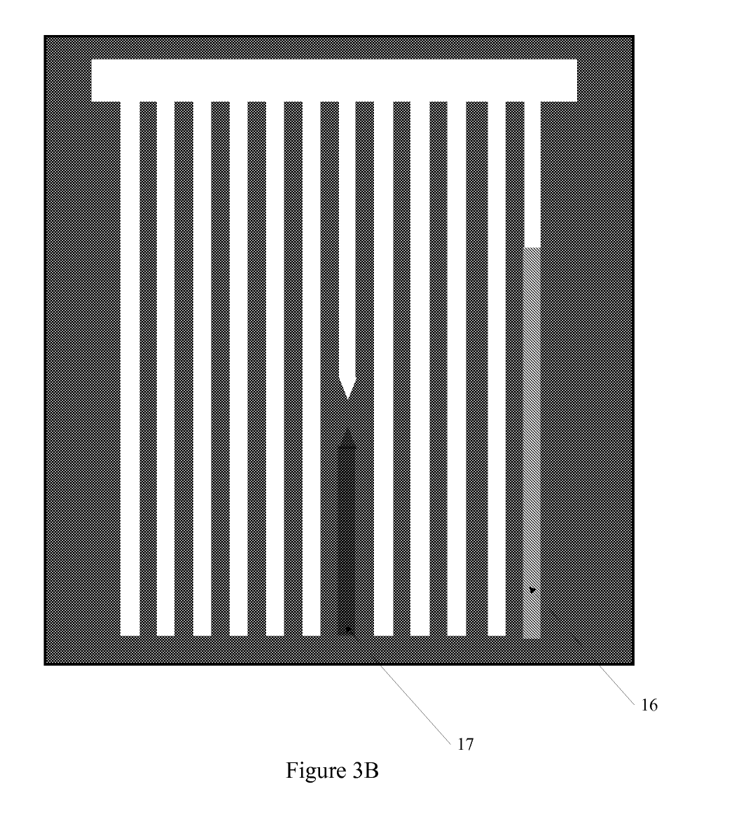

FIGS. 3A and 3B illustrate the application of the inventive test pattern 100 of FIG. 2B to detect one or more defects in the semiconductor device. In an exemplary embodiment of the invention, FIG. 3A illustrates defects 6 that may be formed in one line of the plurality of conductive lines 4 of a semiconductor device. For example, without intending to be limiting, such defects 6 may have been formed as a result of an incorrect recipe in the metal deposition process. FIG. 3B illustrates an image produced by an electron beam radiation according to one embodiment of the invention on the semiconductor device of FIG. 3A.

The illustrative embodiment of FIG. 3A also shows a defective conductive line pattern design comprising a broken line 7 and in addition to the defects 6 comprising pits or even perhaps oxide bridges. Irradiation of the plurality of conductive lines 4 with electron beam radiation results in the image in FIG. 3B. Electrons emitted from the electron beam apparatus accumulate in the non-defective lines. The extent of electrons that may be accumulated in any one of the conductive lines is directly related to the continuous surface area of the conductive line. As a result of accumulation of negative electrons, many of the secondary electrons are emitted from the surfaces of the non-defective lines, resulting in a brighter or whiter image. On the other hand, less electrons accumulate in the defective lines containing pits/oxide bridges or broken lines. Thus, less secondary electrons are emitted from the surfaces, resulting in a darker image. The images thus produced show the presence or absence of defective line patterns.

According to the illustrative embodiment of FIG. 3A, the broken line 7 has a smaller continuous area to accumulate electrons of the electron beam; thus, the image of the broken line 7 is darkest in the segment 17 in FIG. 3B. On the other hand, the pits or oxide bridge defects 6 may prevent electrons passing through the metal line 4 where such defects are locate; thus the shade of segment 16 in FIG. 3B may be between the shade of a line not having any defects and the shade of segment 17 representative of the broken line 7.

As shown in the illustrative embodiment of FIG. 3B, the conductive line deposition quality may be monitored to identify any broken lines and/or defects that may have been formed in any one or more of the conductive lines. Moreover, the continuous area of a normal line may be enlarged due to the conductive interconnecting structure that interconnects all of the conductive lines. Thus, the contrast of the image may be higher and make inspection of the image easier to discern.

An embodiment of the invention is directed to fabricating a semiconductor device imaged with line pattern design. According to an embodiment of the invention, the method of fabricating a semiconductor device that may be subjected to further testing according to the methods further described herein, comprise the steps of providing a substrate; forming a dielectric layer on the substrate; forming a plurality of trenches in the dielectric layer; forming at least one interconnecting trench in the dielectric layer interconnecting the plurality of trenches; and depositing a conductive material in the plurality of trenches and the at least one interconnecting trench.

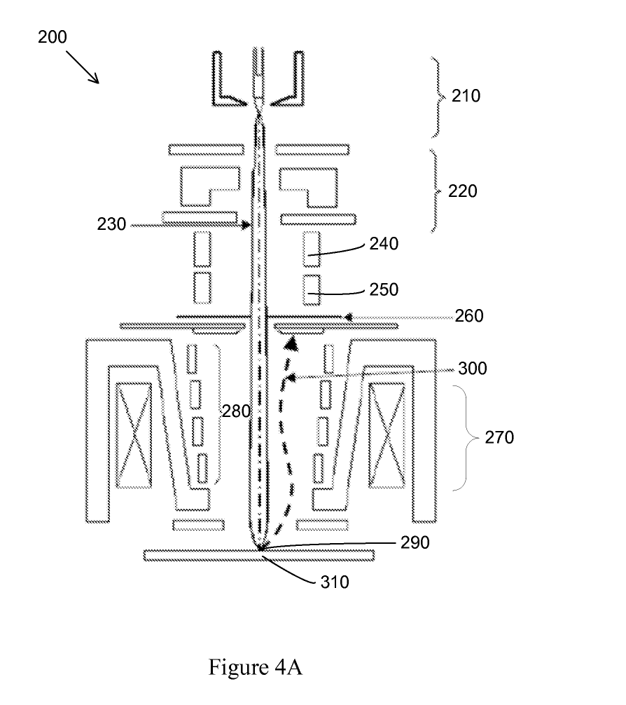

FIG. 4A illustrates an electron beam apparatus that may be used in certain embodiments of the invention. The electron beam apparatus 200 of FIG. 4A may comprise, for example, cathode 210 such as a zirconium oxide/tungsten cathode, for generating an electron beam and a condenser lens 220 for focusing the shape of the electron beam or the primary beam 230 through the remainder of the column. A beam blanker 240 may be used to turn the beam on or off. A stigmator 250 may be used to improve the symmetry of the electron beam. An aperture 260 may be used to limit the size of the electron beam. A lens, such as a magnetic lens, 270 may be used to focus the beam and to refine the shape of the beam. Deflectors 280 may be positioned to isolate the path of the electron beam. Specifically, an in-lens deflector 290 may deflect the electron beam to create secondary and back-scattered electrons 300. That can further be contained by the deflectors 280. A water plane 310 may be used to control the desired beam strength, for example.

An electron beam apparatus similar to that illustrated in FIG. 4A may be used in detecting defects in a semiconductor device. Of course, such a semiconductor device will have a test pattern, for example, a test pattern of the invention. The semiconductor device may generally comprise a substrate, a dielectric layer disposed over the substrate, a plurality of conductive line patterns disposed in the dielectric layer, and at least on interconnecting line pattern configured to connect the plurality of line patterns. Any irradiating device may be used in the inventive test procedure. However, according to certain embodiments of the invention, the irradiating device is an electron beam apparatus similar such as the electron beam apparatus illustrated in FIG. 4A, for example. A receiving device is configured to receive data form the irradiating device. In certain embodiments of the invention, an imaging device is used to display an image for the purpose of detecting any one of a surface defect, an internal defect, and any combination thereof.

FIG. 4B shows one embodiment of the inventive test pattern design and how the secondary electrons emitted from the surfaces of conductive line pattern yield an image. For example, an electronic beam generated by an apparatus similar to that described for FIG. 4A may be directed to a patterned image of the invention similar to that shown in FIG. 2B, for example. The imaged patterned may identify conductive lines that are substantially free of defects, which are indicated by “G” 410 in FIG. 4A. Furthermore, as further described herein in association with FIGS. 3A and 3B, conductive lines having one or more defects will be indicated by segments where there are reduced electrons or no electrons at all, and may be illustrated as a darker segment 420.

As further shown in FIG. 4B, according to an embodiment of the invention, an external electrical field generator is located proximate to the test pattern 400 and an external electrical field 430 may be applied to the test pattern 400. Without intending to be bound by theory, the external electrical field 430 allows more electrons to accumulate at the surface 440 of the test pattern 400. Such accumulation of electrons may result in an improvement in the contrast of the image of the test pattern. According to this illustrative embodiment of the invention, the external electric field generator is located above the test pattern 400 and positive charges 450 are directed toward the test pattern 400 to provide a positive external electrical field 430 on the test pattern 400. Due to the positive external electrical field 430, the electrons in the test pattern 400 are attracted to the top surface 440 allowing the contrast of the image of the secondary electrons to become enhanced.

In another embodiment of the invention, the external electrical field generator may be located at an opposite side of the test pattern, and the external electrical field is provided to force the electrons in the test pattern to move toward the surface on the opposite side of the test pattern.

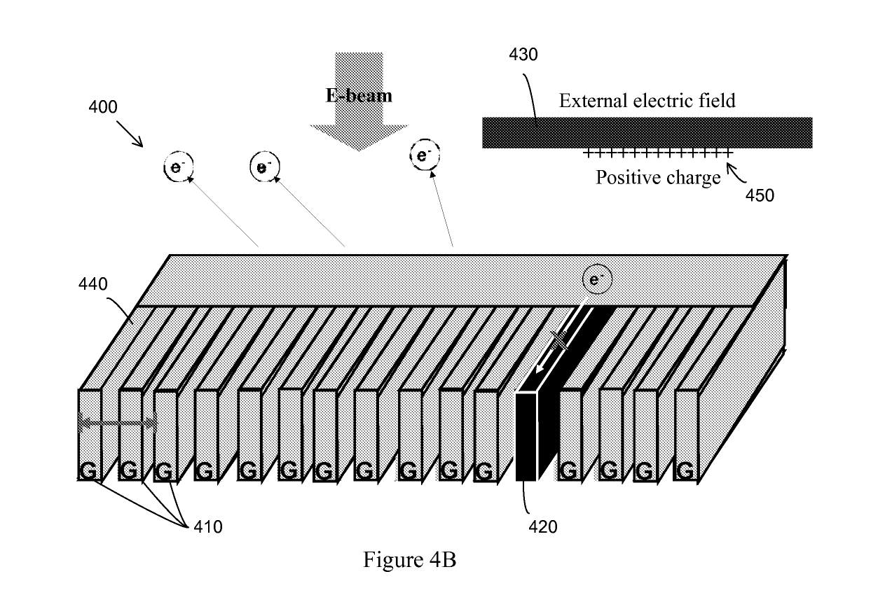

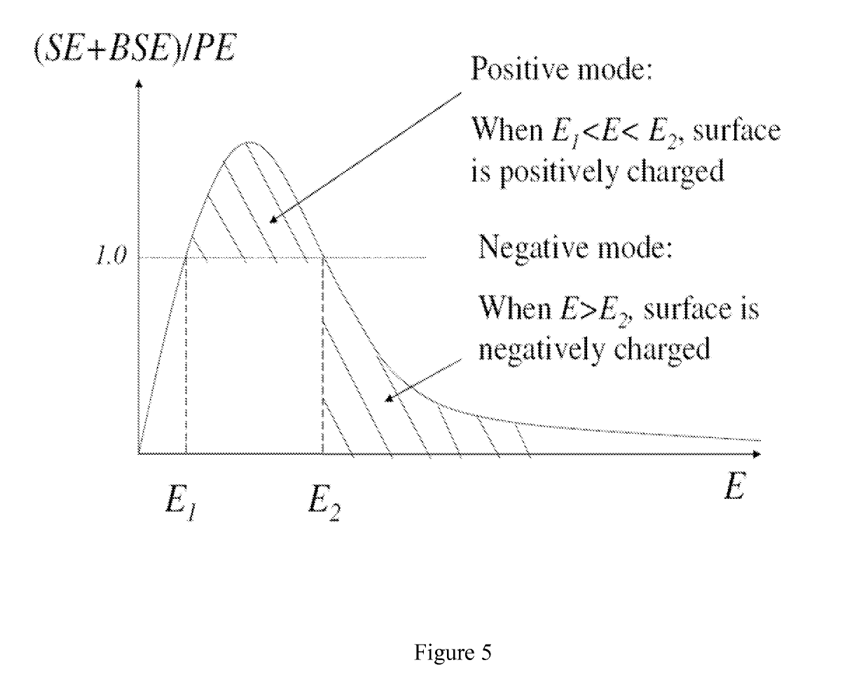

FIG. 5 illustrates an energy diagram of a positive mode and negative mode electron beam radiation. A positive mode electron beam irradiation provides a positively charged surface to the semiconductor device undergoing analysis. A positive mode analysis versus negative mode analysis may be performed by properly selecting an energy of the electron beam. For example, when an energy of the electron beam is between a first energy E1, and a second energy E2, as shown in FIG. 5, a positive mode analysis is performed. In certain embodiments of the invention, when the conducting metal is a copper or copper alloy, for example, a first energy may be about 200 volts and a second energy may be about 1500 volts.

When the electron beam energy exceeds the second energy E2, a negative mode electron beam irradiation is performed by providing a negatively charged surface to the semiconductor device undergoing analysis. As further shown herein, the bright segments and the dark segments of an image obtained using negative mode electron beam irradiation will be reversed in comparison to the corresponding segments in an image obtained using positive mode electron beam irradiation.

Semiconductor fabrication methods demand fast and cost-effective defect detection techniques. Additionally, such methods must also be reliable. Advantageously, the defect inspection methods of the invention may be adapted to perform in-line, continuous analysis of semiconductor devices. Accordingly, such a method involves loading the semiconductor device into a monitoring apparatus. The semiconductor device may comprise a plurality of line patterns that are connected by at least one interconnecting line pattern. In an embodiment of the invention, an electron beam inspection apparatus can be used as a monitoring apparatus in an in-line, continuous method. The semiconductor device may then be scanned, for example, using a responsive stimulus such as electron beam radiation. In the case of an electron beam radiation, the image data in response to the electron beam radiation may be collected and processed to obtain images of the semiconductor substrate. These images may indicate the presence and/or absence of the defects in the semiconductor device under inspection. Batches of semiconductors may be introduced into a monitoring apparatus in a continuous manner, image data may be collected and processed into images indicating the presence of defects or the absence of defects.

Some aspects of the invention include a method of inspection of a semiconductor comprising providing the semiconductor device having a plurality of line patterns disposed on a substrate wherein the plurality of line patterns are connected by at least one interconnecting line pattern, exposing the plurality of line patterns to a responsive stimuli, measuring a response of the plurality of line patterns to the responsive stimuli, wherein the response of the plurality of line patterns indicates any of a presence and absence of a surface defect, an internal defect or combination thereof.

The line patterns of the invention may be straight lines, curved lines or could be representing any other geometrical shape, such as curved, semicircles, circles, squares, rectangle, triangles and the like.

“Surface defects” mean any of the surface defects commonly occurring during a typical semiconductor fabrication process. For example, the surfaces of the conductive line pattern could be uneven, contaminated or chipped or fragmented. The surface defects may or may not be visible to a naked eye.

In some aspects of the invention, the plurality of line patterns may be connected by at least one interconnecting line pattern. The interconnecting line pattern interconnects the plurality of line patterns and forms a unitary line pattern or design. In one particular embodiment of the invention, the plurality of line patterns is parallel to each other. In certain embodiments of the invention, the at least one interconnecting line pattern may be perpendicular to the plurality of line patterns. In certain of embodiments of the invention, the at least one interconnecting line pattern may be proximate to a terminus of the plurality of line patterns. “Interconnecting” means connecting the plurality of line patterns and forming a unitary line design pattern.

In some embodiments of the invention, the plurality of line patterns may be exposed to responsive stimuli. A “responsive stimulus” and/or “responsive stimuli” is any stimulus or stimuli that is/are capable of inducing a response from the plurality of line patterns. In some embodiments of the invention, a semiconductor, such as a semiconductor device or a semiconductor substrate, may comprise the plurality of line patterns that are exposed to the responsive stimuli. In certain embodiments of the invention, the responsive stimuli comprise at least one of an irradiation, a conductance, a magnetic resonance, an acoustical stimulation, and an electrical stimulation. In some particular embodiments, the exposing the plurality of line patterns to the responsive stimuli comprises irradiating the plurality of line patterns with an electron beam radiation. In certain embodiments of the invention, the method may further comprise collecting image data from the electron beam radiation, and developing at least one or more images showing any one of the presence and the absence of the surface defect, the internal defect, and any combination thereof.

In an aspect of the invention, the plurality of line patterns may comprise a plurality of trenches on the surface of the semiconductor device and at least one conducting metal deposited in the plurality of trenches. In this context, “trenches” or “grooves” have the same meaning and may be used interchangeably herein. The trenches or grooves may be formed on the surface of the semiconductor device by any of the etching techniques known in the skill of art.

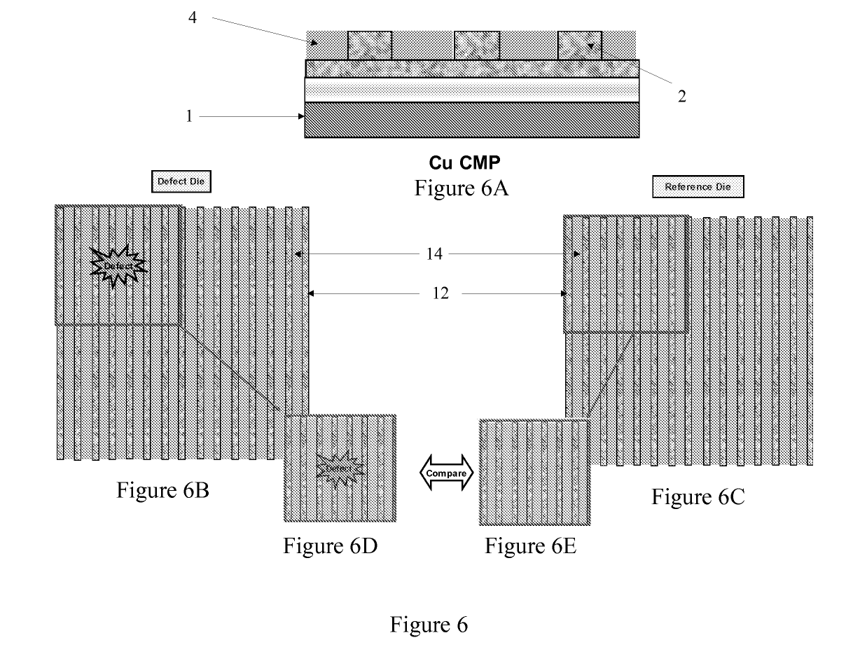

In some embodiments of the invention, the electron beam is supplied by an electron beam inspection tool. Further pursuant to these embodiments, the electron beam inspection tool may be a leap electron beam inspection tool or a continuous electron beam inspection tool. The steps of a leap inspection method are illustrated in FIG. 6, according to an embodiment of the invention. A semiconductor device of FIG. 6A is provided. FIG. 6B illustrates a view of the defect die, while FIG. 6C illustrates a view of the reference die substantially free of any defects. FIG. 6D illustrates an area the defect die where a defect is present. FIG. 6E is a corresponding area of the reference die. The images of FIG. 6D and FIG. 6E are compared to identify the defect in the die having the defect.

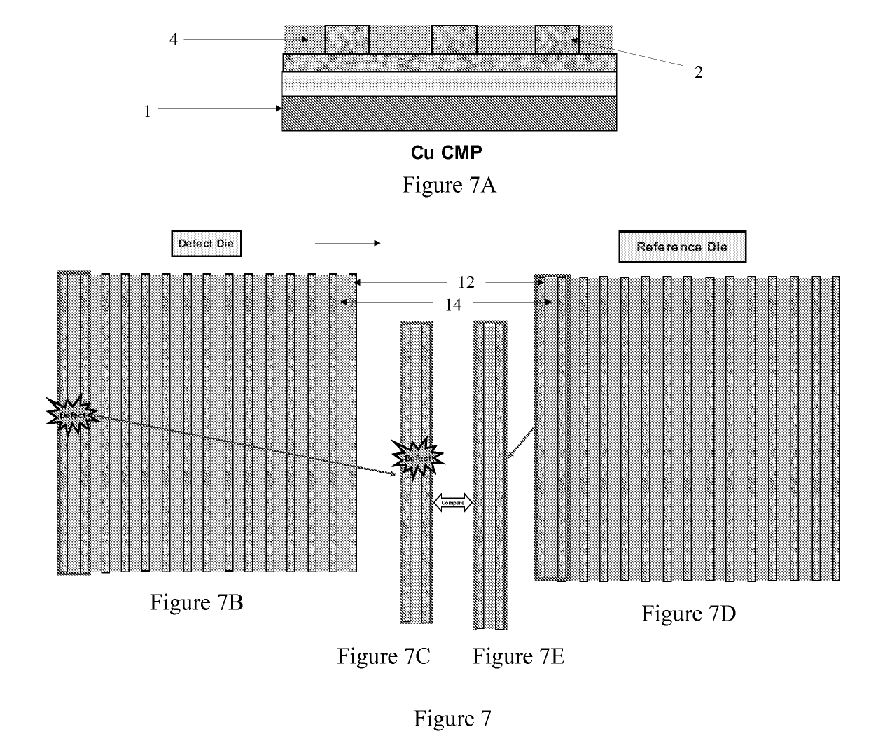

The steps of a continuous scan method are illustrated in FIG. 7, according to an embodiment of the invention. A semiconductor device similar to that illustrated in FIG. 7A is provided. A continuous scan method may involve scanning an entire length of a conductive strip of a defect die illustrated in FIG. 7B having a defect. An image of the entire length of the strip is illustrated in FIG. 7D is obtained. The scanned image of a portion of the defect die having the defect is compared to a corresponding portion of a reference die illustrated in FIGS. 7C and 7E, respectively. A comparison of the scanned portion of the defect die and the scanned portion of the reference die identifies the defect.

In yet other embodiments of the invention, images using both the positive mode electron beam radiation and negative mode electron beam radiation may be used to identify defects in a semiconductor device.

Another aspect of the invention provides a semiconductor device comprising a substrate, a dielectric layer, a plurality of conductive line patterns in the dielectric layer, and at least one interconnecting line pattern configured to connect the plurality of line patterns. Generally, a “substrate” is a semiconductor substrate typical of semiconductor fabrication or in semiconductor technology. In some instances, a substrate is a semiconductor wafer. In some of the embodiments, the substrate is a silicon wafer. In some instances, the dielectric layer is formed on the substrate. In certain embodiments, the plurality of conductive line patterns is parallel. In some such embodiments, the at least one interconnecting line pattern is proximate to a terminus of and perpendicular to the plurality of conductive line patterns. In some embodiments, the dielectric layer comprises a silicon oxide. In some embodiments, the plurality of conductive line patterns comprise copper.

Some embodiments of the invention are directed to a method of fabricating a semiconductor device comprising providing a substrate, forming at least one of a dielectric layer on the substrate, etching a plurality of trenches in the dielectric layer, etching at least one interconnecting trench in the dielectric layer interconnecting the plurality of trenches, and depositing a conductive material in the plurality of trenches and the at least one interconnecting trench. In certain embodiments of the invention, each trench of the plurality of trenches is disposed in parallel to each other. In some embodiments of the invention, the at least one interconnecting trench is disposed perpendicular to the plurality of trenches. In embodiments of the invention, the at least one interconnecting trench is proximate to a terminus of the plurality of trenches. In some embodiments of the invention, the conductive material is selected from the group consisting of aluminum, copper, tungsten, gold, any alloy thereof, and any combination thereof.

Some embodiments of the invention include a method of inspecting a semiconductor device comprising providing the semiconductor device having a substrate, a dielectric layer, a plurality of conductive line patterns disposed in the dielectric layer, and at least one interconnecting conductive line pattern configured to connect the plurality conductive line patterns; irradiating the semiconductor device with an electron beam radiation; receiving image data resulting from the irradiation; and developing an image of the semiconductor device from the image data, wherein the image identifies any one of a presence or an absence of a defect. In certain embodiments of the invention, the method may be an in-line, continuous method. Some embodiments of the invention are directed to an apparatus, method and/or system for detecting at least one of an internal defect and a surface defect of a semiconductor device comprising the steps of providing the semiconductor device having a substrate, a dielectric layer, a plurality of conductive line patterns disposed in the dielectric layer, and at least one interconnecting conductive line pattern configured to connect the plurality conductive line patterns; irradiating the semiconductor device with an electron beam radiation; and receiving image data resulting from the irradiation and developing an image of the semiconductor device from the image data, wherein the image identifies any one of a presence or an absence of a defect.

Some embodiments of the present invention include a system for detecting any one of a defect in a semiconductor device. In such particular embodiments, such a system comprises a semiconductor device having a test pattern. The semiconductor device comprises a substrate, a dielectric layer disposed over the substrate, a plurality of conductive line patterns disposed in the dielectric layer, and at least one interconnecting line pattern configured to connect the plurality of line patterns. Such a system also comprises an irradiating device for providing energy to the test pattern, receiving device to receive data resulting from the irradiating and an imaging device to display an image that detects any one of a defect in the semiconductor device.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. Method of inspection of a semiconductor device comprising:
providing the semiconductor device having a plurality of line patterns disposed on a substrate wherein the plurality of line patterns are connected by an interconnecting line pattern;
exposing the plurality of line patterns to a responsive stimuli; and
measuring a response of the plurality of line patterns to the responsive stimuli, wherein the response of the plurality of line patterns indicates any one of a presence and an absence of a surface defect, an internal defect, and any combination thereof.

2. The method of claim 1, wherein the plurality of line patterns are parallel to each other.

3. The method of claim 2, wherein the interconnecting line pattern is perpendicular to the plurality of line patterns.

4. The method of claim 3, wherein the interconnecting line pattern is proximate to a terminus of the plurality of line patterns.

5. The method of claim 1, wherein the responsive stimuli comprise at least one of an irradiation, a conductance, a magnetic resonance, an acoustical stimulation, and an electrical stimulation.

6. The method of claim 1, wherein the exposing the plurality of line patterns to the responsive stimuli comprises irradiating the plurality of line patterns with an electron beam radiation to provide energy to the plurality of line patterns.

7. The method of claim 6, further comprising:
collecting image data from the electron beam radiation, and
developing at least one or more images showing any one of the presence and the absence of the surface defect, the internal defect, and any combination thereof.

8. The method of claim 1, wherein the plurality of line patterns comprising a plurality of trenches on the surface of the semiconductor device and at least one conducting metal deposited in the plurality of trenches.

9. The method of claim 1, wherein the method is an in-line, continuous process.

10. The method of claim 6, wherein the electron beam radiation is supplied by an electron beam inspection tool, the electron beam inspection tool is a leap electron beam inspection tool or a continuous electron beam inspection tool.

11. The method of claim 1, additionally comprising exposing the semiconductor device to an external electrical field.

12. A semiconductor device comprising:
a substrate;
a dielectric layer disposed on the substrate;
a plurality of conductive line patterns disposed in the dielectric layer; and
at least one interconnecting line pattern configured to connect the plurality of conductive line patterns.

13. The semiconductor device of claim 12, wherein the plurality of conductive line patterns is parallel.

14. The semiconductor device of claim 13, wherein the at least one interconnecting line pattern is proximate to a terminus of and perpendicular to the plurality of conductive line patterns.

15. The semiconductor device of claim 12, wherein the dielectric layer comprises at least one of a silicon oxide and silicon nitride.

16. The semiconductor device of claim 12, wherein the plurality of conductive line patterns comprise copper.

17. A method of fabricating a semiconductor device comprising:
providing a substrate;
forming a dielectric layer on the substrate;
forming a plurality of trenches in the dielectric layer;
forming at least one interconnecting trench in the dielectric layer interconnecting the plurality of trenches; and
depositing a conductive material in the plurality of trenches and the at least one interconnecting trench.

18. The method of claim 17, wherein the plurality of trenches are disposed in parallel to each other.

19. The method of claim 17, wherein the at least one interconnecting trench is disposed perpendicular to the plurality of trenches.

20. The method of claim 19, wherein the at least one interconnecting trench is proximate to a terminus of the plurality of trenches.

21. The method of claim 17, wherein the conductive material is selected from the group consisting of aluminum, copper, tungsten, gold, any alloy thereof, and any combination thereof.

22. A system for detecting a defect in a semiconductor device comprising:
the semiconductor device having a test pattern, the semiconductor device comprising;
a substrate;
a dielectric layer disposed over the substrate;
a plurality of conductive line patterns disposed in the dielectric layer; and at least one interconnecting line pattern configured to connect the plurality of line patterns;
an irradiating device for providing energy to the test pattern;
a receiving device to receive data resulting from the irradiating device; and
an imaging device to display an image that detects any one of a surface defect, an internal defect, and any combination thereof in the semiconductor device.

23. The system of claim 22, additionally comprising an external electric field generator located proximate to the substrate.
